(19) United States
(12) Patent Application Publication
(10) Pub. No.: US 2016/0358796 A1
(43) Pub. Date: Dec. 8, 2016

(54) Cable drive robot mechanism for exchanging samples

(71) Applicant: DONGFANG JINGYUAN ELECTRON LIMITED, Beijing (CN)

(72) Inventors: Yuhai Mu, Fremont, CA (US); Lei Jiang, Beijing (CN); Zongqiang Yu, Beijing (CN)

(21) Appl. No.: 15/166,045

(22) Filed: May 26, 2016

Related U.S. Application Data
(63) Continuation of application No. PCT/CN2016/079641, filed on Apr. 19, 2016.
Application No. PCT/CN2016/079641 is a continuation-in-part of application No. 14/730,136, filed on Jun. 3, 2015.

(51) Int. Cl. H01L 21/67; H01L 21/677; B25J 9/10; B25J 18/04; B25J 9/00

(52) U.S. Cl. CPC H01L 21/67288; B25J 18/04; B25J 9/0087; B25J 9/1045; H01L 21/67742; H01L 21/67213; H01L 21/67201

(57) ABSTRACT

Techniques of swapping two samples with a mechanical arm that has no backlash, no friction, no particle contamination are described. With the unique structure and the material used for the cables, the mechanical arm provides considerable operating life. When used in a semiconductor inspection system, the mechanical arm, also referred to herein a cable drive robot mechanism, can be advantageously used to swap two wafers as part or within the inspection system. The two wafers, one examined and the other one yet to be examined, can be swapped between two chambers. During the exchanging process, the cable drive robot mechanism seamlessly picks up an examined wafer to exit one chamber while loading up an unexamined wafer to enter another chamber at the same time.

### CROSS-REFERENCE TO RELATED APPLICATION

This is a continuation-in-part of co-pending U.S. application Ser. No. 14/730,136, entitled “Drive Mechanism for OPTO-Mechanical Inspection System”, filed on Jun. 3, 2015.

### BACKGROUND OF THE INVENTION

1. Field of the Invention

The present invention is related to the area of semiconductor inspection system, and more particularly related to techniques of swapping two samples with a mechanical arm that has no backlash, no friction, no particle contamination and is of considerable operating life. The two samples may be two wafers, one has been examined and the other one is yet to be examined, where the mechanical arm, also referred to herein a cable drive robot mechanism, can be advantageously used to swap the two wafers as part or within an inspection system.

2. Description of the Related Art

Moore's Law states that the number of transistors on integrated circuits doubles every two years, which offers increased transistor density, cost scaling, and performance per watt. Shrinking of node sizes is essential for Moore's Law to work. With the shrinking sizes becoming tens of nanometers, the defects on a specimen have to be controlled within a certain range in order to ensure the function and yield of manufactured chips.

With tighter design limits and the escalating need to increase yield and reduce semiconductor manufacturing costs, defect inspection to detect and classify defects in compound semiconductor processing is more critical than ever. As the size of defects becomes smaller and smaller along with the development of the integrated circuit (IC) designs, inspection of defects becomes increasingly difficult. For example, the resolution for an optical inspection tool is no long good enough to inspect hot spots smaller than 20 nm when the wavelength of the optical source is 193 nm. Accordingly, electron beam inspections are introduced and can provide a relatively high resolution to detect much smaller defects on a specimen for hot spots identification, inspection and review.

Most of the defects that cause a silicon wafer defective are a result of contamination to the silicon wafer. Contamination is defined as a foreign material at the surface of the silicon wafer or within the bulk of the silicon wafer. The contamination can be particles or ionic contamination, liquid droplets and etc. Besides affecting the formation of geometric features in a designed circuit, particle contamination can cause a chip to lose proper functions, often leading to the complete failure of the chip. In general, there are three main sources in which particle contamination could happen: production environment, wafer transmission and wafer exchanging in process equipment. Among the three main sources, particle contamination in wafer exchanging in process happens the most. Therefore, effective particle control in wafer exchanging equipment is critical to yield enhancement.

Charged particle beam inspection equipment is very important in semiconductor manufacturing process. It can quickly in-situ identify, inspect and further review hot spots on a specimen. It is required that the particles are introduced as little as possible when conducting defects inspection, otherwise the defects analysis would be affected and the lower yield of chips could happen. In an existing e-beam inspection system, particles may be generated when an examined wafer and an unexamined wafer are exchanged. In this disclosure, a cable drive robot mechanism used for wafer exchange is disclosed.

The cable drive robot mechanism has no backlash, no friction, no particle contamination and with an infinite working life, because the cable material is with high strength and high stiffness. It is very useful for the charged particle beam inspection equipment, which requires high transmission accuracy and especially no-contamination.

In this disclosure, a mechanical arm with cable drive rotation mechanism is described. One of the advantages, objectives and benefits of the cable drive rotation mechanism is of high precision in rotation, great reliability and durability, and has no backlash and no particle contamination.

### SUMMARY OF THE INVENTION

This section is for the purpose of summarizing some aspects of the present invention and to briefly introduce some preferred embodiments. Simplifications or omissions may be made to avoid obscuring the purpose of the section. Such simplifications or omissions are not intended to limit the scope of the present invention.

In general, the present invention is related to techniques of swapping two samples with a mechanical arm that has no backlash, no friction, no particle contamination and is of considerable operating life. When used in a semiconductor inspection system, the mechanical arm, also referred to herein a cable drive robot mechanism, can be advantageously used to swap two wafers as part or within the inspection system. The two wafers, one examined and the other one yet to be examined, can be swapped between an inspection chamber and a preparation (e.g., load lock) chamber. During the exchanging process, the cable drive robot mechanism seamlessly picks up the examined wafer to exit the inspection chamber while loading up the unexamined wafer to enter the inspection chamber.

According to one aspect of the present invention, the mechanical arm includes a fixed pulley driven by a motor, a first pulley mounted with a first handler, a second pulley mounted with a second handler, and a first pair and a second pair of up-side and down-side cables. Both of the cables are made from a material that does not produce particles when in operation. Further both ends of the up-side and the down-side cables in the first pair are respectively secured on the first and the fixed pulleys, and both ends of the up-side and the down-side cables in the second pair are respectively secured on the second and the fixed pulleys.

According to still another aspect of the present invention, the first and second pulleys are caused to rotate synchronously when the fixed pulley is driven to rotate, each of the first and second pulleys is pulled to rotate by one of the up-side and down-side cables respectively in the first and second pair.

According to still another aspect of the present invention, the material of the up-side and down-side cables is metal. Depending on implementation, the metal is one of aluminum, tungsten, elgiloy steel and stainless steel.

According to still another aspect of the present invention, a band or cable drive rotation mechanism is provided, there is no relative movement between a cable and a pulley so to minimize possible friction between the cable and the pulley. With a proper material selected for the cables and the pulleys, there are no contamination particles produced in the rotation process, the surface of samples being moved can be free of contamination all the time.

According to yet another aspect of the present invention, the wear and tear is minimized on either the cable or the pulley. As a result, this driving mechanism enjoys an advantage of substantial operating life. It is an ideal driving mechanism for an inspection system that requires only less than one full rotation.

Many objects, features, benefits and advantages, together with the foregoing, are attained in the exercise of the invention in the following description and resulting in the embodiment illustrated in the accompanying drawings.

### BRIEF DESCRIPTION OF THE DRAWINGS

These and other features, aspects, and advantages of the present invention will become better understood with regard to the following description, appended claims, and accompanying drawings where:

FIG. 1 shows a perspective view of an internal structure according to one embodiment of the invention;

FIG. 2A shows a perspective view of an exemplary cable drive robot mechanism according to one embodiment of the present invention;

FIG. 2B shows a corresponding cross-section view of the cable drive robot mechanism of FIG. 2A;

FIG. 3 shows a view for the transmission principle of the cable drive robot mechanism of FIG. 2A or FIG. 2B;

FIG. 4 shows a sketch illustrating the angle range that a cable drive robot mechanism can rotate in one embodiment;

FIG. 5A and FIG. 5B are two respective views for illustrating a spring loaded pushing force generating mechanism that may be used in the cable drive robot mechanism 104 of FIG. 1;

FIG. 6A, 6B and 6C are respective views for illustrating another cable tension adjustment method used in the cable drive robot mechanism 104 of FIG. 1;

FIG. 6D shown how an end of the cable may be winded; and

FIG. 7 is a flow chart for explaining the wafer exchanging steps according to the embodiment of the present invention.

### DETAILED DESCRIPTION OF THE PREFERRED EMBODIMENTS

The detailed description of the present invention is presented largely in terms of procedures, steps, logic blocks, processing, or other symbolic representations that directly or indirectly resemble the operations of mechanical devices. These descriptions and representations are typically used by those skilled in the art to most effectively convey the substance of their work to others skilled in the art. Numerous specific details are set forth in order to provide a thorough understanding of the present invention. However, it will become obvious to those skilled in the art that the present invention may be practiced without these specific details. In other instances, well known methods, procedures, components, and circuitry have not been described in detail to avoid unnecessarily obscuring aspects of the present invention.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments.

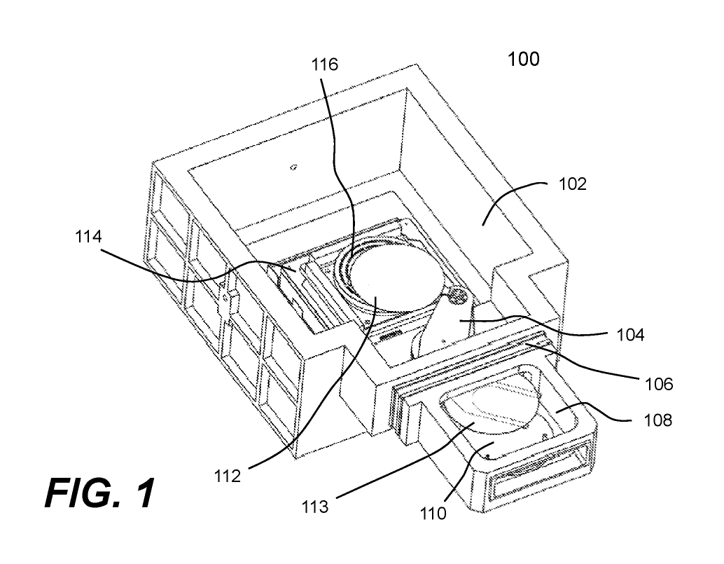

Embodiments of the present invention are discussed herein with reference to FIGS. 1-7. However, those skilled in the art will readily appreciate that the detailed description given herein with respect to these figures is for explanatory purposes as the invention extends beyond these limited embodiments.

The present invention pertains to a mechanism that can be used advantageously for wafer exchanging, for example, in an inspection system (e.g., charged particle beam inspection equipment). According to one aspect of the present invention, the mechanism, also referred to as cable drive robot mechanism, has no backlash, no friction, no particle contamination and a substantial long working life if not infinite. As will be described further below, the material used in the cable drive robot mechanism is of high strength and high stiffness. Such a mechanism is very useful for the charged particle beam inspection equipment which requires high transmission accuracy and especially has no-contamination.

Referring now to FIG. 1, it shows a perspective view of an internal structure 100 according to one embodiment of the invention. The structure 100 may be enclosed in or part of an inspection system, such as wafer inspection equipment or electronic beam inspection system. As shown in FIG. 1, the structure 100 comprises a main chamber 102, a cable drive robot mechanism 104, a gate valve 106, a load lock chamber 108, a wafer lift pin 110, two wafers 112 and 113, a stage 114 and an electrostatic chuck 116. While the wafer 112 (labeled as Wa) is being examined under a focused beam (not shown) in the center of the main chamber 102, an unexamined wafer 113 (labeled as Wb) is being prepared in the load lock chamber 108. The two wafers 112 and 113 are to be swapped or exchanged when the wafer 112 is done with an inspection in the main chamber 102.

In operation, after the wafer 112 is done for inspection, the stage 114 carrying the wafer 112, assumed to be moving along x or y axis, is shifted to a wafer exchange position. The gate valve 106 is then opened. At the same time, the wafer lift pin 110 in the load lock chamber 108 vertically lifts the unexamined wafer 113 to the wafer exchanging position. A wafer lift pin (not shown) within the electrostatic chuck 116 in the main chamber 102 lifts the examined wafer 112 vertically to the wafer exchanging position. Next, the cable drive robot mechanism 104 is operated to move to the wafer exchanging position so as to exchange the wafers 112 and 113. Afterwards, the two lift pins in both sides descend to the original position to put down the two wafers 112 and 113 on the cable drive robot mechanism 104. Then the cable drive robot mechanism 104 is caused to rotate to an opposite wafer exchanging position, where the wafer 112 is in the load lock chamber 108 while the wafer 113 is in the main chamber 102. Further, the two lift pins in both sides lift again to the wafer exchanging position, so the cable drive robot mechanism 104 can now be rotated to the initial position. Then the gate valve 106 is closed and the wafer lift pin within the electrostatic chuck 116 pulls down so that the unexamined wafer 113, now in the chamber 102, can be inspected.

In operation, the x-y stage 114 is moved to the center of the main chamber 102 so as to start the examination of the wafer 113. During this period, the examined wafer 112 is exited from the load lock chamber 108 while an unexamined wafer is newly introduced into the load lock chamber 108. The examination for the new wafer follows as soon as the examination for the wafer 113 in the main chamber 102 is completed.

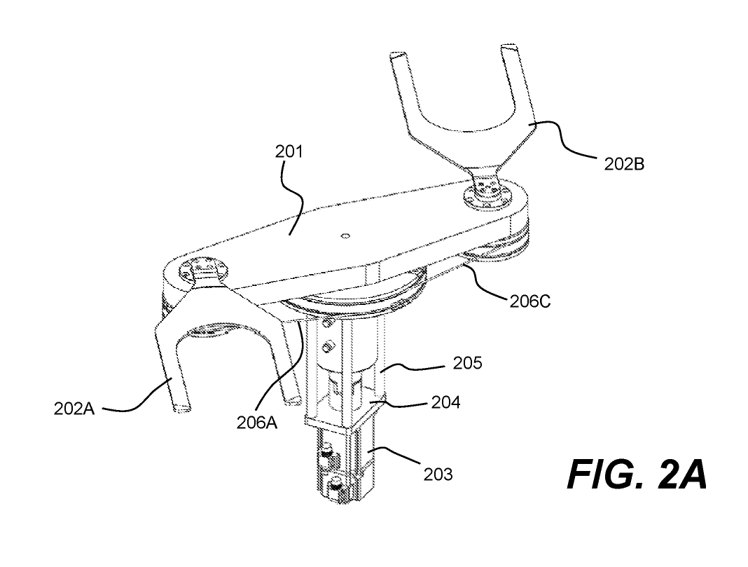

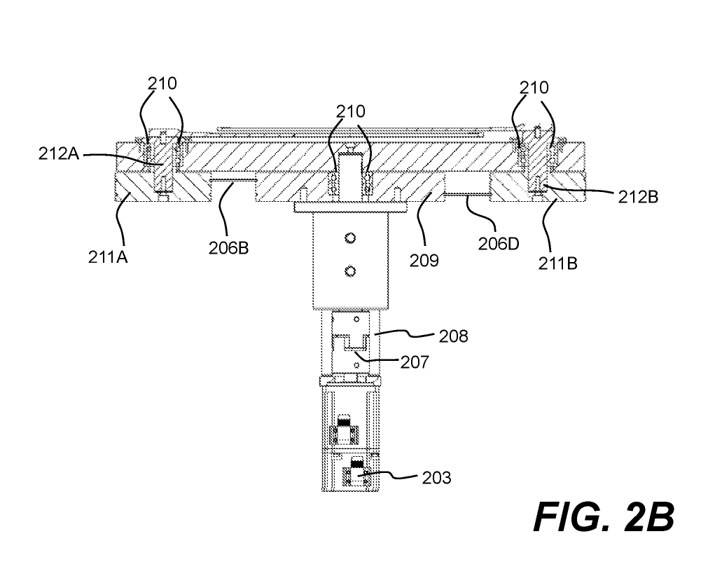

As described above, the cable drive robot mechanism 104 is designed to exchange an examined wafer with an unexamined wafer at the same time. One of important features, objects and advantages of this design is to shorten the time required for wafer exchanging so as to enhance the throughput of an inspection system when employed therein. Referring now to FIG. 2A, it shows a perspective view of an exemplary cable drive robot mechanism 200 according to one embodiment of the present invention. FIG. 2B shows a corresponding cross-section view of the cable drive robot mechanism 200. The cable drive robot mechanism 200 may be used in FIG. 1 to swap the two wafers 112 and 113. As shown in FIG. 2A, the cable drive robot mechanism 200 includes a rotating arm 201, two wafer hands 202A and 202B, a servo motor 203, a motor adapter 204, a motor connector 205, four cable 206A, 206B, 206C and 206D, a coupling 207, a magnetic bearing 208, a fixed pulley 209, six roller bearings 210, two rotating pulley 211A and 211B, two connecting shafts 212A and 212B.

According to one embodiment, the fixed pulley 209 is mounted in the main chamber 102 of FIG. 1. Specifically, the fixed pulley 209 is mounted to the servo motor 203 through the motor adapter 204 and the motor connector 205. The rotating arm 201 is connected with the magnetic bearing 208 which is connected with the coupling 207. The servo motor 203 is also connected with the coupling 207. So the rotating arm 201 is caused to rotate in association with the rotation of the servo motor 203. The connecting shafts 212A and 212B are supported by the rotating arm 201 through the roller bearings 210 so as to be rotatable. Both the two wafer hands 202A and 202B and the two rotating pulley 211A and 211B are fixed to the connecting shafts 212A and 212B so that they can be rotated synchronously. According to one embodiment, one end of the cable 206A or 206B is fixed to the fixed pulley 209 and the other end of the cable 206A or 206B is fixed to the rotating pulley 211A, the same is applied to the cable 206C or 206D, and the rotating pulley 211B. As will be further detailed below, the four cables 206A, 206B, 206C and 206D should be arranged properly to ensure that they will not interfere with each other.

In operation, when the rotating arm 201 is driven by the servo motor 203 to rotate, the two rotating pulley 211A and 211B are caused to rotate through the four cables 206A, 206B, 206C and 206D because the two ends of each cable are fixed. Further the two wafer hands 202A and 202B are rotated in association with the rotation of the two rotating pulleys 211A and 211B so that they can exchange an examined wafer and an unexamined wafer at the same time.

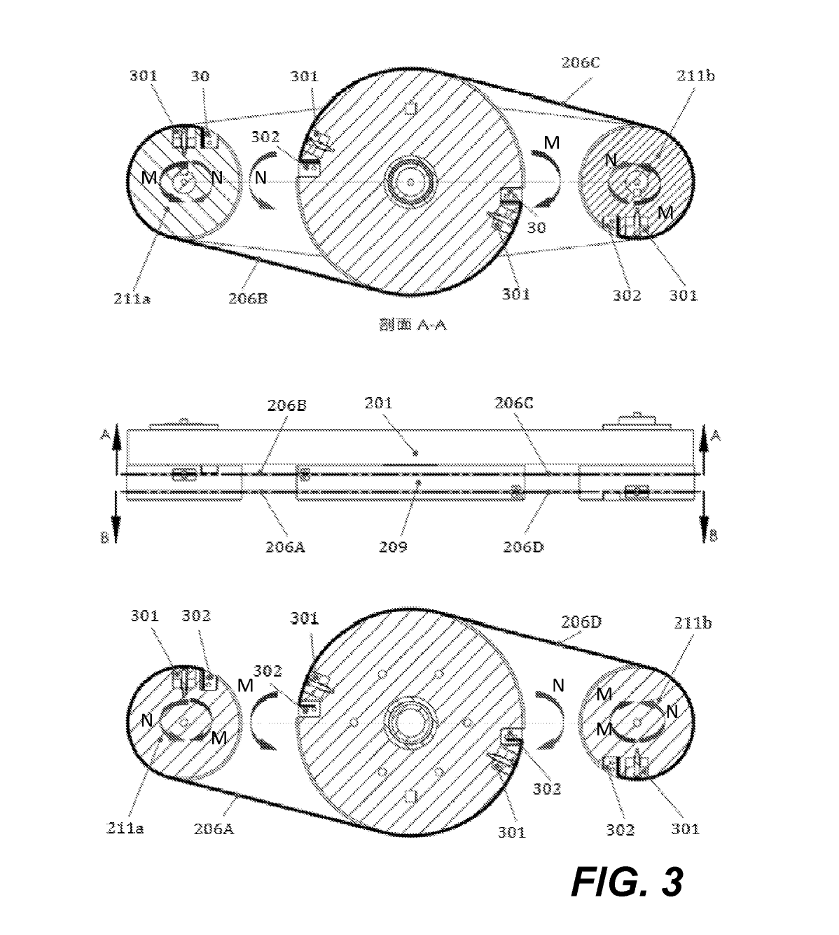

Referring now to FIG. 3, it shows a view for the transmission principle of the cable drive robot mechanism 200 of FIG. 2A or FIG. 2B. As shown in FIG. 3, there are eight tension devices 301 and eight fixing blocks 302. The cables 206A and 206B are arranged in section A-A and the cable 206B and 206C are arranged in section B-B. One end of the cable is fixed to the fixed pulley 209 and the other end of the cable is fixed to either on of the two rotating pulley 211A or 211B with fixing blocks 301. The tension devices 301 are respectively used for cable tension adjusting mechanism and installed at the end of the four cables 206A, 206B, 206C and 206D.

Referring to section A-A, when the rotating arm 201 is rotated according to an arrow M the cables 206B and 206C shall twine onto the fixed pulley 209 in the circumferential direction. As a result, the cables 206B and 206C are released from the two rotating pulleys 211A and 211B because the cables are tense. Then the two rotating pulley 211A and 211B are rotated according to the arrows M. Referring to the section B-B, when the two rotating pulleys 211A and 211B are rotated according to the red arrow, the cables 206A and 206D are forced to release from the fixed pulley 209 and twine onto the two rotating pulleys 211A and 211B. Then the two wafer hands 202A and 202B are rotated in association with the rotation of the two rotating pulleys 211A and 211B. In the section B-B, when the rotating arm 201 is rotated according to an arrow N, the transmission principle is the same as when the rotating arm 201 is rotated according to the arrow M.

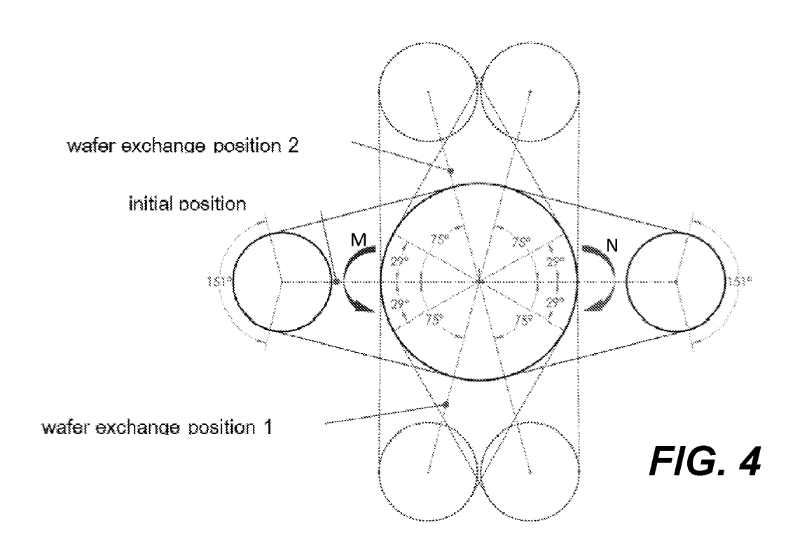

FIG. 4 shows a sketch illustrating the angle range that a cable drive robot mechanism can rotate in one embodiment. The cable drive robot mechanism has three stop positions. When the x-y stage 114 is caused to carry an examined wafer and shift to a wafer exchange position, the rotating arm 201 is rotated to the wafer exchange position 1 according to the arrow M. Then the rotating arm 201 is rotated to the wafer exchange position 2 according to the arrow N. Eventually, the rotating arm 201 is rotated to the initial position according to the arrow M to wait for the next wafer exchanging operation. During the rotation, not only should the length of the four cables be arranged properly to ensure that they are not interfered with each other, but also the overlap length on the fixed pulley 209 and the two rotating pulleys 211A and 211B are long enough to meet the rotation angle.

In one embodiment, the radio between the fixed pulley and the two rotating pulleys is set to 1:2. So the two rotating pulleys 211A and 211B are rotated to 150° when the fixed pulley 209 is rotated to 75° initially. Referring to the section A-A in FIG. 3, when the rotating arm 201 is rotated to the wafer exchange position 1 according to the arrow M, the tension device 301 and the fixing block 302 must be designed within 29° to ensure that the cable 206b and 206c would not interfere with each other after twining onto the fixed pulley 209, where the tension device 301 and the fixing block 302 must be designed beyond 151° to ensure that the overlap length on the two rotating pulleys 211A and 211B is long enough after the cables 206B and 206C are released.

Referring now to the section B-B in FIG. 3, when the rotating arm 201 is rotated to the wafer exchange position 1 according to the arrow M, the tension device 301 and the fixing block 302 must be designed within 29° to ensure that the overlap length on the fixed pulley 209 is long enough after the cables 206A and 206D are released, where the tension device 301 and the fixing block 302 must be designed beyond 151° to ensure that the cables 206A and 206D are not to be interfered with themselves after twining onto the two rotating pulleys 211A and 211B. The positions of the tension device 301 and the fixing block 302 are the same when the rotating arm 201 is rotated to the wafer exchange position 2 according to the arrow N, because they are symmetrical.

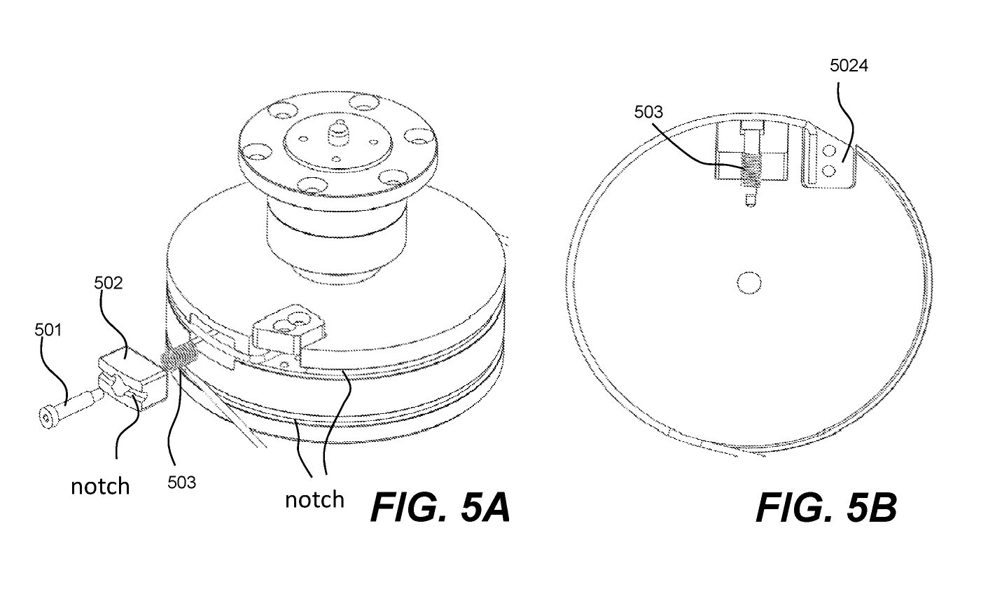

FIG. 5A and FIG. 5B are two respective views for illustrating a spring loaded pushing force generating mechanism that may be used in the cable drive robot mechanism 104 of FIG. 1. The spring loaded pushing force generating mechanism comprises a shoulder screw 501, a spring holding block 502, a stiff enough spring 503 and a fixing block 504. The spring 503 is installed between the slot of a pulley and the spring holding block 502. Then the shoulder screw 501 is used to hold the spring holding block 502 and the spring 503 on the right position. The spring holding block 502 is pushed by the compressed spring 503 to move outward in the direction of the radius of the pulley and the direction is guided by the shoulder screw 501 as well. The cable is lying inside of the notch designed on the spring holding block 502, so the movement of the spring holding block 502 is pushing the cable to be tighter. The end of the cable and the fixing block 504 are welded together, then it is mounted on the pulley with screws after selecting the spring with the right stiffness to let the cable get an optimized tension. The cable tension is optimized by using the described tension adjustment method, so there is no-backlash in the driving mechanism, which is very critical to the high precision movement process in the e-beam inspection system. Two notches are machined on the outer surface of each pulley and work as tracks to confine the cable from running off the outer surface of the pulleys.

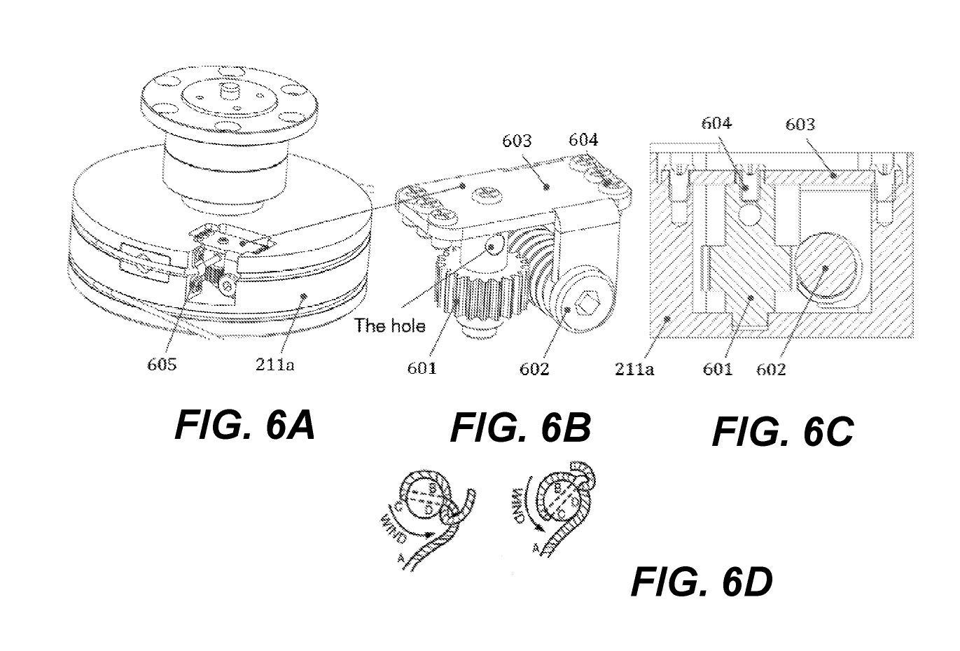

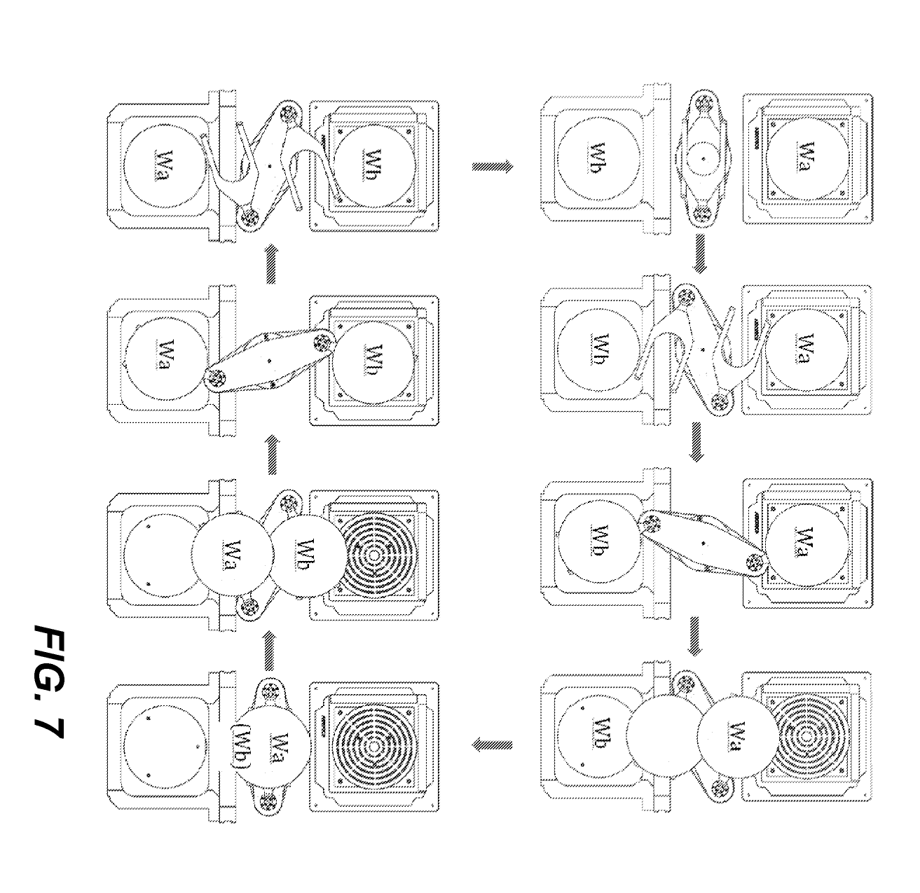

FIG. 6A, 6B and 6C are respective views for illustrating another cable tension adjustment method used in the cable drive robot mechanism 104 of FIG. 1. It comprises a worm gear 601, a worm driver 602, a mounting plate 603, cross head screws 604 and a cable limit sheet 605. As shown in FIG. 6B and FIG. 6C, the worm driver 602 is first installed on the slot of the mounting plate 603, then the worm gear 601 is installed on the mounting plate 603 and fixed by the cross head screws 604. After that, one can insert the end of the cable through the hole in the worm gear 601 and wind the end of the cable according to FIG. 6D. Some excess cable should be left to make sure that the cable can wind around the worm gear shaft a few (e.g., 3 to 4) rounds, otherwise the cable would loosen up after the cable drive robot mechanism is running for some time. Then the assembly can be installed on the two rotating pulleys 211A and 211B and fixed by the cross head screws 604 as shown in FIG. 6A. Then the cable limit sheet 605 which confine the cable from running off the outer surface of the pulleys can be mounted on both of the rotating pulleys 211A and 211B by the cross head screws 604. Then the worm driver 602 can be rotated by a tool (e.g., Allen wrench) to ensure that the cable tension is optimized. The worm gear mechanism is used in the cable tension adjustment method, because it has an interlock function which the worm gear 601 can be driven by the worm driver 602, but the worm driver 602 cannot be driven by the worm gear 601. So the cable will not loosen up after the cable tension is optimized by rotating the worm driver 602 using an Allen wrench. This is very critical to the high precision movement process in the driving mechanism. The cable tension adjustment method is easy to install and operate and have high reliability.

FIG. 7 is a flow chart for explaining the wafer exchanging steps according to the embodiment of the present invention. It is assumed that the steps take place in an e-beam inspection system. Those skilled in the art can appreciate that the same or the substantially similar steps could be implemented in other devices. The initial state is assumed that a wafer is being examined under a focused beam in the center part of the main chamber 102 of FIG. 1, an unexamined wafer which will be examined next is being prepared in the load lock chamber 108 FIG. 1 and the cable drive robot mechanism is in its initial position.

As shown in FIG. 7 and in operation, the x-y stage 107 carrying the examined wafer 112 is shifted to a wafer exchange position and the gate valve 106 is opened so as to communicate the load lock chamber 108 with the main chamber 102. Next, the wafer lift pin 110 in the load lock chamber 108 vertically lift the unexamined wafer 113 to the wafer exchanging position and the wafer lift pin within the electrostatic chuck 116 in the main chamber 102 vertically lift the examined wafer 112 to the wafer exchanging position. At this moment, the cable drive robot mechanism 104 is rotated to the wafer exchanging position 1. The wafer lift pin 110 and the wafer lift pin within the electrostatic chuck 116 descend to the original position to put the two wafers 112 and 113 respectively on the wafer hands 202A and 202B. Next, the cable drive robot mechanism 104 is rotated to the opposite wafer exchanging position 2 according to the arrow N in FIG. 4. Next, the wafer lift pin 110 and the wafer lift pin within the electrostatic chuck 116 lift again to withdraw the wafers 112 and 113. At this moment, the cable drive robot mechanism 104 is rotated to the initial position according to the arrow M in FIG. 4. Next, the gate valve 106 is closed and the wafer lift pin within the electrostatic chuck 108 pulls down so that the unexamined wafer 113 can be chucked. Next, the x-y stage 114 carrying the unexamined wafer 113 is moved to the center of the main chamber 102 so as to start the examination of the wafer 113. Eventually, the examined wafer 112 is exited from the load lock chamber 108 while another unexamined wafer is introduced into the load lock chamber 108. The examination for the new wafer continuously follows as soon as the examination at present is completed.

The present invention has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the invention as claimed. Accordingly, the scope of the present invention is defined by the appended claims rather than the foregoing description of embodiments.

What is claimed is:

1. A mechanical arm comprising:
a fixed pulley driven by a motor;
a first pulley mounted with a first handler;
a second pulley mounted with a second handler; and
a first pair and a second pair of up-side and down-side cables, both of the cables made from a material that does not produce particles when in operation, wherein both ends of the up-side and the down-side cables in the first pair are respectively secured on the first and the fixed pulleys, and both ends of the up-side and the down-side cables in the second pair are respectively secured on the second and the fixed pulleys.

2. The mechanical arm as recited in claim 1, wherein the first and second pulleys are caused to rotate synchronously when the fixed pulley is driven to rotate, each of the first and second pulleys is pulled to rotate by one of the up-side and down-side cables respectively in the first and second pair.

3. The mechanical arm as recited in claim 2, wherein the mechanical arm is used in an inspection system to swap two samples initially positioned oppositely.

4. The mechanical arm as recited in claim 3, wherein the material of the up-side and down-side cables is metal.

5. The mechanical arm as recited in claim 4, wherein the metal is one of aluminum, tungsten, elgiloy steel and stainless steel.

6. The mechanical arm as recited in claim 3, wherein the inspection system is a semiconductor wafer inspection system provided to defect defects on a surface of a wafer, and the first and second handlers are first and second wafer hands provided to hold up two respective wafers while the fixed pulley is driven to rotate the first and second pulleys.

7. The mechanical arm as recited in claim 6, wherein one of the two wafers is examined and the other one of the two wafers is unexamined.

8. The mechanical arm as recited in claim 7, wherein the examined wafer is lifted up from a stage in a first chamber and loaded upto the first wafer hand, and the unexamined wafer is lifted up from a stage in a second chamber and loaded upto the second wafer before the fixed pulley is driven to rotate the first and second pulleys.

9. The mechanical arm as recited in claim 8, wherein the first chamber is an inspection chamber, wherein the examined wafer has been examined with an electronic beam, and the second chamber is load lock chamber provided to exit an examined wafer and load a new unexamined wafer.

10. The mechanical arm as recited in claim 2, wherein at least two separate circumferential notches are made into a pulley to serve as two separate tracks to confine the up-side and the down-side cabled so as to prevent the up-side and down-side cables from running off the pulley, wherein the pulley is one of the fixed pulley and the first and second pulleys.

11. The mechanical arm as recited in claim 10, wherein the pulley includes at least one tension device and one fixing block, the tension device and fixing block are next to each other and embedded into the pulley, wherein the fixing block is provided to secure an end of a cable, and the tension device is provided to adjust tension of the cable.

12. The mechanical arm as recited in claim 11, wherein the tension on each of the up-side and down-side cables is optimized when stiffness of the spring is in accordance with a predefined stiffness.

13. The mechanical arm as recited in claim 12, the tension device and the fixing block are designed within 29° to ensure that an overlap length of each of the up-side and down-side cables on the fixed pulley is long enough after the cables are released.

14. The mechanical arm as recited in claim 11, wherein the tension device includes a spring loaded pushing force generating mechanism that further includes:
a notch;
a spring;
a spring holding block;
a shoulder screw, wherein the spring is compressed and held up by the spring holding block, the shoulder screw is used to hold the spring holding block and the spring in the notch of the first disk.

15. The mechanical arm as recited in claim 11, wherein the tension device includes a spring loaded pushing force generating mechanism that further includes:
a worm gear;
a worm driver;
a mounting plate;
cross head screws; and
a cable limit sheet to confine the cable from running off the outer surface of the pulleys, wherein the worm driver is installed on a slot of the mounting plate, the worm gear is then installed on the mounting plate and fixed by the cross head screws.

16. The mechanical arm as recited in claim 1, wherein the mechanical arm is part or within a semiconductor inspection system and used to exchange two wafers, one being examined and the other being unexamined, the mechanical arm is caused to operate to move the examined wafer to the position of the unexamined wafer while moving the unexamined wafer to the position of the examined wafer.
